(19) United States
(12) Patent Application Publication
(10) Pub. No.: US 2011/0026301 A1
(43) Pub. Date: Feb. 3, 2011

(54) SEMICONDUCTOR MEMORY DEVICE

(76) Inventor: Susumu Ozawa, Kawasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/844,239

(22) Filed: Jul. 27, 2010

(30) Foreign Application Priority Data
Aug. 3, 2009 (JP) 2009-180875

(51) Int. Cl. G11C 11/00

(52) U.S. Cl. 365/148

(57) ABSTRACT

According to one embodiment, a semiconductor memory device includes first select line groups laminated in a vertical direction, and each including first select lines extending in a first direction, second select line groups alternately laminated with the first select line groups, and each including second select lines extending in a second direction that intersects with the first direction, and memory cells arranged between the first select lines and the second select lines. Even-numbered layers and odd-numbered layers of the first select line groups are arranged to be shifted in the second direction.

### CROSS-REFERENCE TO RELATED APPLICATIONS

This application is based upon and claims the benefit of priority from Japanese Patent Application No. 2009-180875, filed Aug. 3, 2009; the entire contents of which are incorporated herein by reference.

### FIELD

Embodiments described herein relate generally to a semiconductor memory device.

### BACKGROUND

Nonvolatile semiconductor memories are widely used as storage devices of electronic devices such as personal computers (PCs), mobile telephones, digital cameras, personal digital assistants (PDAs). As the nonvolatile semiconductor memory, a phase-change random access memory (PCRAM), resistive RAM (ReRAM) or magnetic RAM (MRAM) that uses variable resistance elements as memory cells is developed.

It is known that two types of operation modes are provided in the variable resistance element used in the ReRAM. One of the operation modes is to selectively set a high-resistance state and low-resistance state by switching the polarity of an application voltage and the element is called a bipolar type. The other operation mode is to selectively set a high-resistance state and low-resistance state by controlling a voltage and voltage application time without switching the polarity of an application voltage and the element is called a uni-polar type.

When the uni-polar type is used, a memory cell array can be configured by arranging “series-connected variable-resistance elements and rectifier elements such as diodes” in intersection areas between bit lines and word lines. Further, by 3-dimensionally laminating memory cell arrays, the memory capacity can be increased without increasing the array area (Jpn. Pat. Appln. KOKAI Publication No. 2009-130139).

In the memory cell array with the 3-dimensional structure, since bit lines BL and word lines intersecting therewith at right angles are regularly arranged, memory cells are arranged in the same position in the vertical direction. Therefore, it becomes difficult to maintain the flatness between an area in which the memory cells are arranged and another area and variations in the flatness are superimposed for each lamination. As a result, the shapes of the memory cells and interconnections are distorted and, finally, it becomes impossible to form a laminated structure.

### BRIEF DESCRIPTION OF THE DRAWINGS

FIG. 1 is a layout diagram showing the chip configuration of a resistance-change memory according to a first embodiment;

FIG. 2 is a perspective view showing the structure of a memory cell array 20 according to the first embodiment;

FIG. 3 is a cross-sectional view showing the structure of a memory cell MC;

FIG. 4 is a circuit diagram of an extracted part of the memory cell array 20;

FIG. 5 is a bird's-eye view of the memory cell array 20;

FIG. 6 is a side view of the memory cell array 20 as viewed in an X-direction;

FIG. 7 is a perspective view showing the structure of lead-out interconnections;

FIG. 8 is a perspective view showing the structure of a memory cell array 20 according to a second embodiment;

FIG. 9 is a bird's-eye view of the memory cell array 20;

FIG. 10 is a side view of the memory cell array 20 as viewed in an X-direction;

FIG. 11 is a perspective view showing the structure of a memory cell array 20 according to a third embodiment;

FIG. 12 is a bird's-eye view of the memory cell array 20; and

FIG. 13 is a side view of the memory cell array 20 as viewed in a Y-direction.

### DETAILED DESCRIPTION

In general, according to one embodiment, there is provided a semiconductor memory device comprising: first select line groups laminated in a vertical direction, and each including first select lines extending in a first direction; second select line groups alternately laminated with the first select line groups, and each including second select lines extending in a second direction that intersects with the first direction; and memory cells arranged between the first select lines and the second select lines. Even-numbered layers and odd-numbered layers of the first select line groups are arranged to be shifted in the second direction.

The embodiments will be described hereinafter with reference to the accompanying drawings. In the description which follows, the same or functionally equivalent elements are denoted by the same reference numerals, to thereby simplify the description.

### First Embodiment

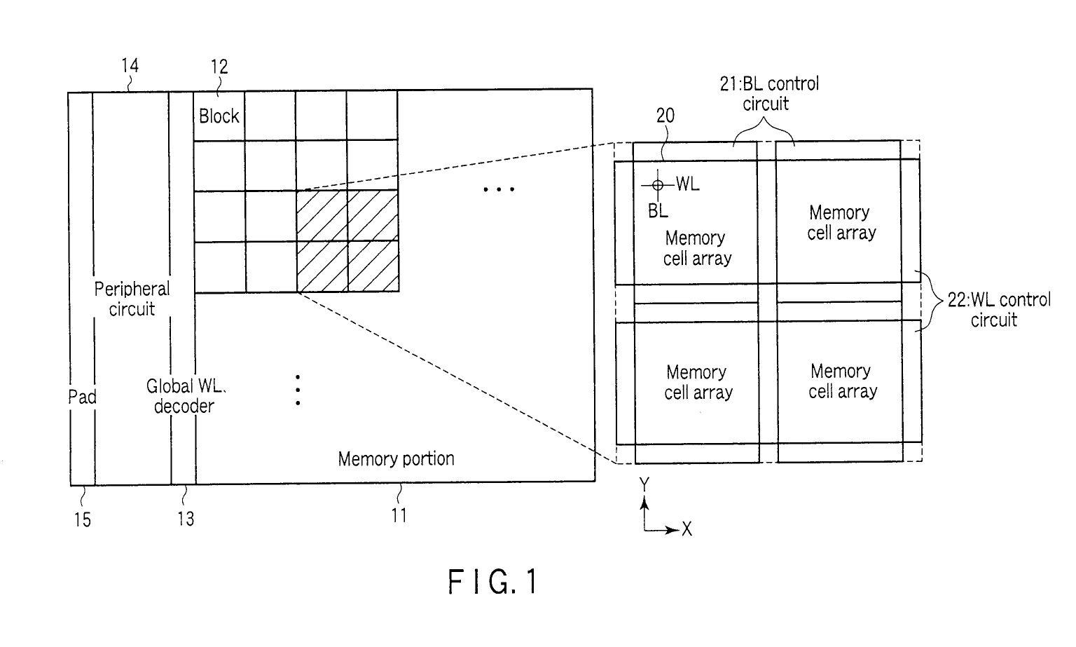

FIG. 1 is a layout diagram showing the chip configuration of a resistance-change memory (semiconductor memory device) according to a first embodiment.

A memory portion 11 that functions as storing data includes a plurality of blocks 12. Each block 12 comprises a memory cell array 20, BL control circuits 21 that select and control bit lines BL arranged in the memory cell array 20 and WL control circuits 22 that select and control word lines WL arranged in the memory cell array 20. The BL control circuits 21 are provided on both sides of the memory cell array 20 in a Y-direction. The WL control circuits 22 are provided on both sides of the memory cell array 20 in an X-direction.

A global WL decoder 13 is connected to plural global WLs (not shown) to select the global WL. The global WLs are arranged in the memory portion 11 and connected to the WL control circuits 22. One global WL is provided in correspondence to a preset number of word lines (local WLs), for example, 16 word lines WL contained in the block 12. One of the 16 word lines WL is connected to one global WL by the WL control circuit 22 at the data write or read time. A peripheral circuit 14 can be commonly utilized by the plural blocks 12 by using the above hierarchical word line system.

The peripheral circuit 14 is connected to the global WL decoder 13 and BL control circuits 21. The peripheral circuit 14 comprises a state machine that controls various operations of the resistance-change memory, a voltage generation circuit that generates various voltages used at the data write and read time, a command interface that processes a command supplied from the exterior, a data buffer that temporarily stores input/output data, an address register that temporarily stores an address, and the like. A pad 15 includes plural electrodes and permits the resistance-change memory to be electrically connected to the external circuit via the pad 15.

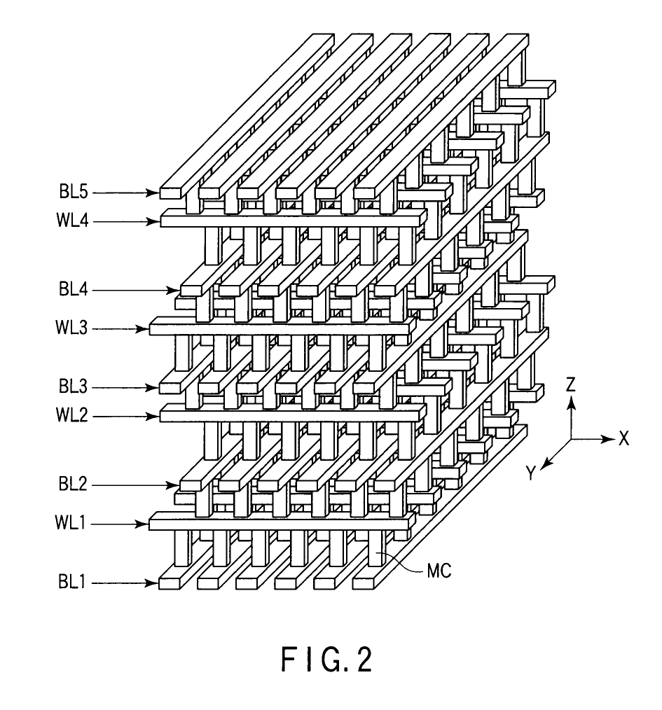

FIG. 2 is a perspective view showing the structure of the memory cell array 20 contained in each block 12. The memory cell array 20 is configured by laminating plural memory cell units each of which is two-dimensionally arranged in a vertical direction (Z-axis direction). Each memory cell MC is arranged in an intersection area between the bit line (first select line) BL extending in the Y-direction and a word line (second select line) WL extending in the X-direction and electrically connected to the above lines. That is, the resistance-change memory of this embodiment is a cross-point resistance-change memory and is a resistance-change memory with a 3-dimensional structure.

The memory cell array 20 includes laminated interconnection layers of plural levels. In FIG. 2, a case wherein first-level to ninth-level interconnection layers are laminated, that is, the memory cells MC of eight layers are laminated is shown as one example, but the number of laminated layers is not limited to this case and is determined according to the restriction of the peripheral circuit and the manufacturing method.

In the first-level interconnection layer, a bit line group BL1 including plural bit lines extending in the Y-direction is arranged. In the second-level interconnection layer, a word line group WL1 including plural word lines extending in the X-direction is arranged. Likewise, in the third-level to ninth-level interconnection layers, bit line groups BL2 to BL5 and word line groups WL2 to WL4 are alternately arranged. That is, in the memory cell array 20, plural bit line groups BL and plural word line groups WL are alternately laminated.

In the following explanation, plural bit lines contained in the interconnection layer of the same level, that is, the bit line group of one layer is represented by BLm and plural bit lines contained in bit line group BLm are represented by BLm_1, BLm_2, BLm_3, for example. Likewise, plural word lines contained in the interconnection layer of the same level, that is, the word line group of one layer is represented by WLn and plural word lines contained in word line group WLn are represented by WLn_1, WLn_2, WLn_3, for example.

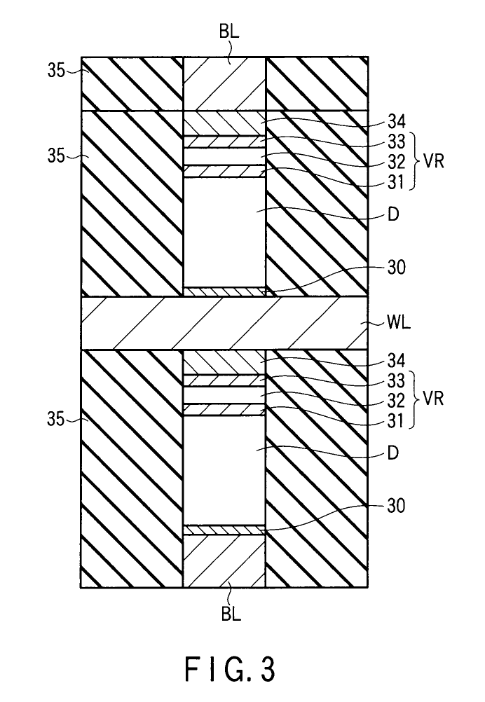

FIG. 3 is a cross-sectional view showing the structure of one memory cell MC. The memory cell MC is configured by a variable resistance element VR used as a memory element and a select element (for example, diode) D that are serially connected between bit line BL and word line WL. As an interconnection material that forms bit line BL, for example, tungsten (W) is provided. A barrier film 30 is provided on bit line BL to prevent silicon (Si) that forms the diode D from being diffused into a metal of bit line BL. As the barrier film 30, for example, titanium nitride (TiN) is provided. The diode D is formed of silicon (Si) used as a semiconductor material is provided on the barrier film 30. As the diode D, for example, a PIN diode configured by an N-type semiconductor layer, P-type semiconductor layer and intrinsic semiconductor layer (I layer) sandwiched between the above two layers is used.

The variable resistance element VR is provided on the diode D. The variable resistance element VR is configured by laminating a lower electrode 31, resistance-change film 32 and upper electrode 33. The lower electrode 31 also functions as a barrier film to prevent silicon (Si) forming the diode D from being diffused into the resistance-change film 32. As the lower electrode 31 and upper electrode 33, for example, titanium nitride (TiN) is provided. As the resistance-change film 32, for example, a transition metal oxide is used and, specifically, NiOₓ, CoOₓ, TiOₓ or the like is used.

The variable resistance element VR takes at least two-value resistances as bi-stable states at room temperatures by applying a voltage or supplying a current thereto. By writing and reading the two stable resistances, at least two-value memory operations can be realized. If the variable resistance element VR is operated to perform the binary memory operation, for example, the low-resistance state of the resistance-change film 32 is set to correspond to “1” and the high-resistance state thereof is set to correspond to “0”. The operation of changing the state from the high-resistance state to the low-resistance state is referred to as “set” and the reverse operation is referred to as “reset”.

A conductive protection film 34 that protects the variable resistance element VR and functions as a stopper at the time of a chemical mechanical polishing (CMP) step is formed on the variable resistance element VR. As the protection film 34, for example, tungsten (W) is provided. Word line WL is provided on the protection film 34. As an interconnection material forming word line WL, for example, tungsten (W) is provided. Adjacent memory cells MC are isolated from each other by means of interlayer insulating layers 35 formed around the memory cells. As the interlayer insulating layer 35, for example, polysilazane is provided. Thus, the memory cell MC is formed.

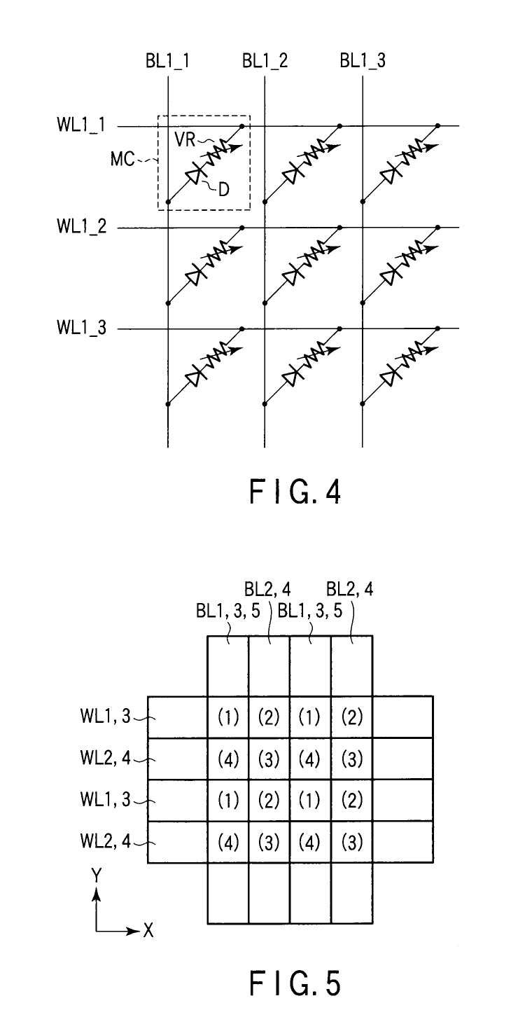

FIG. 4 is a circuit diagram of an extracted part of the memory cell array 20 and shows bit line group BL1, word line group WL1 and plural memory cells MC connected thereto. In FIG. 4, three bit lines BL1_1 to BL1_3 of bit line group BL1 and three word lines WL1_1 to WL1_3 of word line group WL1.

As described before, the memory cell MC is configured to include the series-connected variable resistance element VR and diode D. One end of the variable resistance element VR is connected to word line WL1_n. The other end of the variable resistance element VR is connected to the cathode of the diode D. The anode of the diode D is connected to bit line BL1_m. The connection relationship of the diode D is adequately set according to the configuration of the peripheral circuit of the resistance-change memory and the configuration of the resistance-change memory 32. Thus, the cross-point resistance-change memory is configured.

As shown in FIG. 2, bit line group BL2 is shifted in the X-direction with respect to the adjacent bit line group BL1 with word line group WL1 disposed therebetween. Bit line groups BL of plural layers are laminated with the above relationship maintained. That is, the bit line groups of odd-numbered layers and the bit line groups of even-numbered layers are shifted with respect to one another in the X-direction. For example, the shifting distance is set to half the pitch of the bit lines in the interconnection layer of the same level. In this case, the pitch indicates the total length of the width of one bit line BL and the distance between bit lines BL. In this embodiment, the width of bit line BL and the distance between bit lines BL are respectively set to half the pitch.

Word line group WL2 is shifted in the Y-direction with respect to the adjacent word line group WL1 with bit line group BL2 disposed therebetween. Word line groups WL of plural layers are laminated with the above relationship maintained. That is, the word line groups of odd-numbered layers and the word line groups of even-numbered layers are shifted with respect to one another in the Y-direction. For example, the shifting distance is set to half the pitch of the word lines in the interconnection layer of the same level. In this embodiment, the width of word line WL and the distance between word lines WL are respectively set to half the pitch.

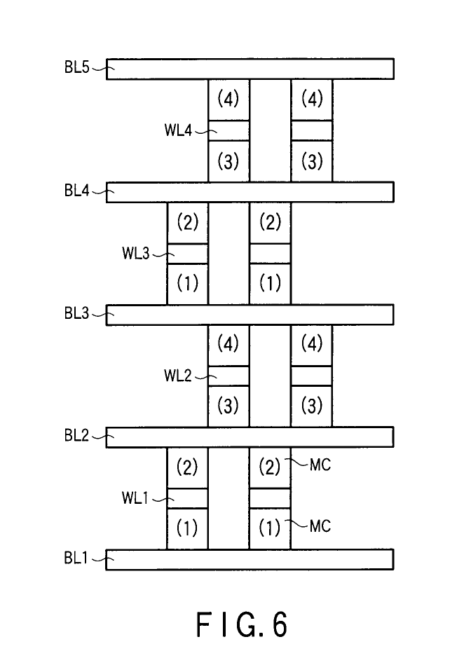

FIG. 5 is a bird's-eye view of the memory cell array 20. FIG. 6 is a side view of the memory cell array 20 as viewed in the X-direction. In FIG. 6, numbers are attached to the respective memory cells MC. The same number is attached to the memory cells MC that are arranged in the same level, that is, that are connected to the same bit line group and word line group and the same number is also attached to the memory cells MC that are arranged in the same position in the bird's-eye view. The numbers in FIGS. 5 and 6 represent the common memory cells MC.

First, it can be understood from FIG. 5 that bit line groups BL1, BL3, BL5 of the odd-numbered layers and bit line groups BL2, BL4 of the even-numbered layers are shifted by half the pitch in the X-direction. Specifically, bit line groups BL1, BL3, BL5 of the odd-numbered layers are arranged in the same positions in the bird's-eye view of FIG. 5. Bit line groups BL2, BL4 of the even-numbered layers are arranged in the same positions in the bird's-eye view of FIG. 5.

Likewise, it can be understood from FIG. 5 that word line groups WL1, WL3 of the odd-numbered layers and word line groups WL2, WL4 of the even-numbered layers are shifted by half the pitch in the X-direction. Specifically, word line groups WL1, WL3 of the odd-numbered layers are arranged in the same positions in the bird's-eye view of FIG. 5. Word line groups WL2, WL4 of the even-numbered layers are arranged in the same positions in the bird's-eye view of FIG. 5.

Further, as is understood from FIGS. 5 and 6, the memory cells MC are uniformly arranged in the memory cell array 20. In the conventional memory in which the bit lines themselves and word lines themselves are laminated in the same pattern, no memory cells are arranged around one memory cell. That is, the memory cells are not uniformly arranged. In this embodiment, even if memory cells MC of plural layers are laminated, the flatness of each layer can be maintained since the memory cells MC are uniformly arranged. Therefore, the memory cell array 20 in which variation in the shape is suppressed and distortion is reduced can be configured.

(Structure of Lead-out Interconnections of Bit Lines and Word Lines)

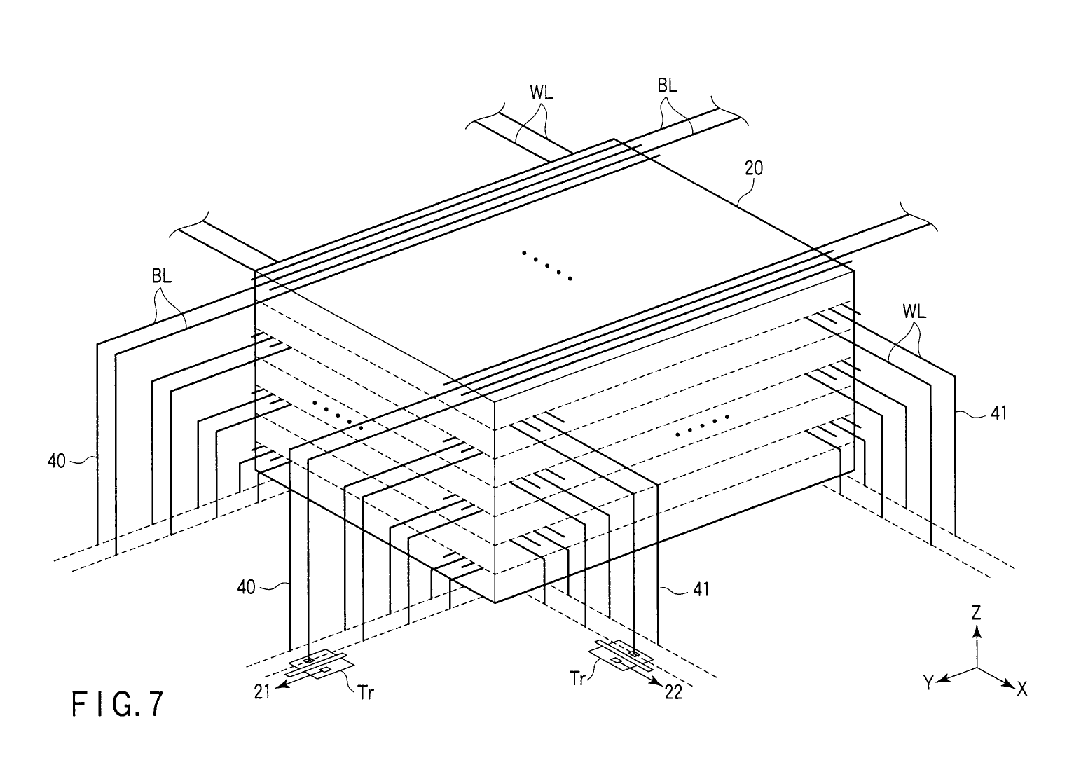

Next, the structure of the lead-out interconnections to respectively lead out bit lines BL and word lines WL to the BL control circuits 21 and WL control circuits 22 is explained. FIG. 7 is a perspective view showing the structure of the lead-out interconnections. In FIG. 7, the laminated structure of memory cells of six layers, that is, the laminated structure containing bit lines BL1 to BL4 is shown.

Bit lines BL contained in the interconnection layer of the same level are alternately led out on both sides of the memory cell array 20 in the Y-direction. That is, half (for example, odd-numbered bit lines BL) of the plural bit lines BL contained in the interconnection layer of the same level are led out on one side of the memory cell array 20 in the Y-direction and the remaining half bit lines (for example, even-numbered bit lines BL) are led out on the other side of the memory cell array 20 in the Y-direction. In this case, bit lines BL are led out more outwardly as they are arranged on the more upward layer.

The end portion of each bit line BL on the lead-out side is connected to a corresponding one of via interconnections 40 that extend in the Z-direction (vertical direction). Each via interconnection 40 extends to the semiconductor substrate and is connected to one end of the current path of a select transistor Tr formed on the semiconductor substrate. The other end of the current path of the select transistor Tr is connected to the BL control circuit 21 that is also formed on the semiconductor substrate. In FIG. 7, the structure of the via interconnections 40 on one side and bit lines BL connected thereto is shown, but the via interconnections 40 on the other side and bit lines BL connected thereto have the same structure.

Word lines WL contained in the interconnection layer of the same level are alternately led out on both sides of the memory cell array 20 in the X-direction. That is, half (for example, odd-numbered word lines WL) of the plural word lines WL contained in the interconnection layer of the same level are led out on one side of the memory cell array 20 in the X-direction and the remaining half word lines (for example, even-numbered word lines WL) are led out on the other side of the memory cell array 20 in the X-direction. In this case, word lines WL are led out more outwardly as they are arranged on the more upward layer.

The end portion of each word line WL on the lead-out side is connected to a corresponding one of via interconnections 41 that extend in the Z-direction (vertical direction). Each via interconnection 41 extends to the semiconductor substrate and is connected to one end of the current path of a select transistor Tr formed on the semiconductor substrate. The other end of the current path of the select transistor Tr is connected to the WL control circuit 22 that is also formed on the semiconductor substrate. In FIG. 7, the structure of the via interconnections 41 on one side and word lines WL connected thereto is shown, but the via interconnections 41 on the other side and word lines WL connected thereto have the same structure.

As described above, in the first embodiment, in the cross-point resistance-change memory having the memory cells MC arranged in the intersection areas between bit lines BL and word lines WL, two-dimensionally arranged memory cell units of plural layers are laminated. In this case, bit line groups BL and word line groups WL are alternately laminated. Further, the odd-numbered bit line groups and even-numbered bit line groups are arranged to shift from one another by half the pitch. Likewise, the odd-numbered word line groups and even-numbered word line groups are arranged to shift from one another by half the pitch.

Therefore, according to the first embodiment, the memory cells MC can be uniformly arranged and the flatness of each layer can be maintained even if the memory cells MC are vertically laminated. Thus, a resistance-change memory in which the memory cells MC and interconnections are less distorted and the memory cells MC and interlayer insulating layers have less defects can be realized. As a result, a resistance-change memory including memory cells MC having less characteristic variation can be configured.

Further, since the flatness of each of the layers with the three-dimensional structure can be maintained, a larger number of layers can be laminated to configure the memory cell array 20. As a result, a resistance-change memory having higher recording density can be realized.

### Second Embodiment

In a second embodiment, odd- and even-numbered layers of only word line groups are arranged to shift from one another. That is, laminated bit line groups are arranged in the same positions in the vertical direction, and the word line groups of the odd-numbered layers and the word line groups of the even-numbered layers among the laminated word line groups are arranged to shift from one another by half the pitch, for example.

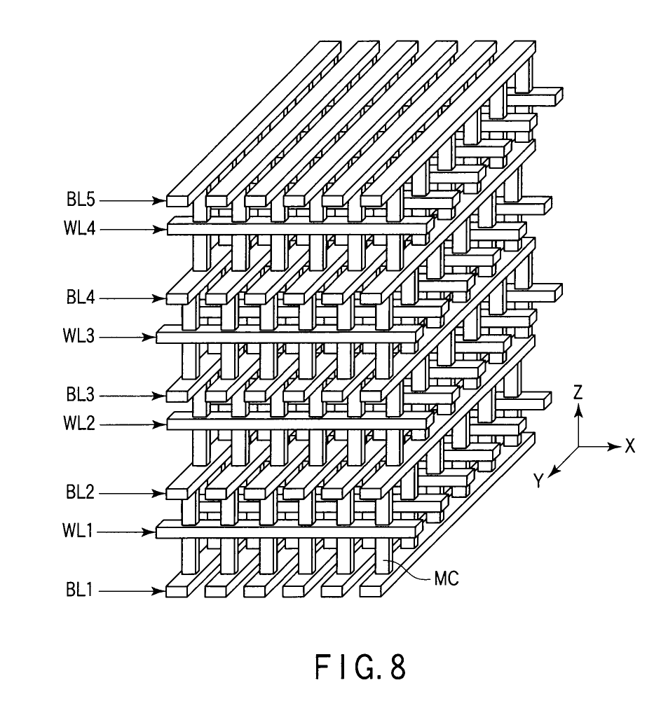

FIG. 8 is a perspective view showing the structure of a memory cell array 20 according to the second embodiment. In the memory cell array 20, bit line groups BL and word line groups WL are alternately laminated in a Z-direction. In FIG. 8, a case wherein memory cells MC of eight layers are laminated is shown as one example, but the number of laminated layers is not limited to this case and can be determined according to the restriction of the peripheral circuit and the manufacturing method. Each memory cell MC is arranged in an intersection area between a bit line BL extending in a Y-direction and a word line WL extending in an X-direction and is electrically connected thereto.

As shown in FIG. 8, a word line group WL2 is shifted in the Y-direction with respect to a word line group WL1 that is adjacent thereto with a bit line group BL2 disposed therebetween. Word line groups WL of plural layers are laminated with the above relationship maintained. That is, the word line groups of the odd-numbered layers and the word line groups of the even-numbered layers are arranged to be shifted in the Y-direction. For example, the shifting distance is set to half the pitch of the word lines in the interconnection layer of the same level. Further, the width of word line WL and the distance between word lines WL are set to half the pitch.

Bit line groups BL are arranged in the same positions in the vertical direction. That is, unlike the word line groups, bit line groups BL of the odd-numbered layers and bit line groups BL of the even-numbered layers are arranged without being shifted.

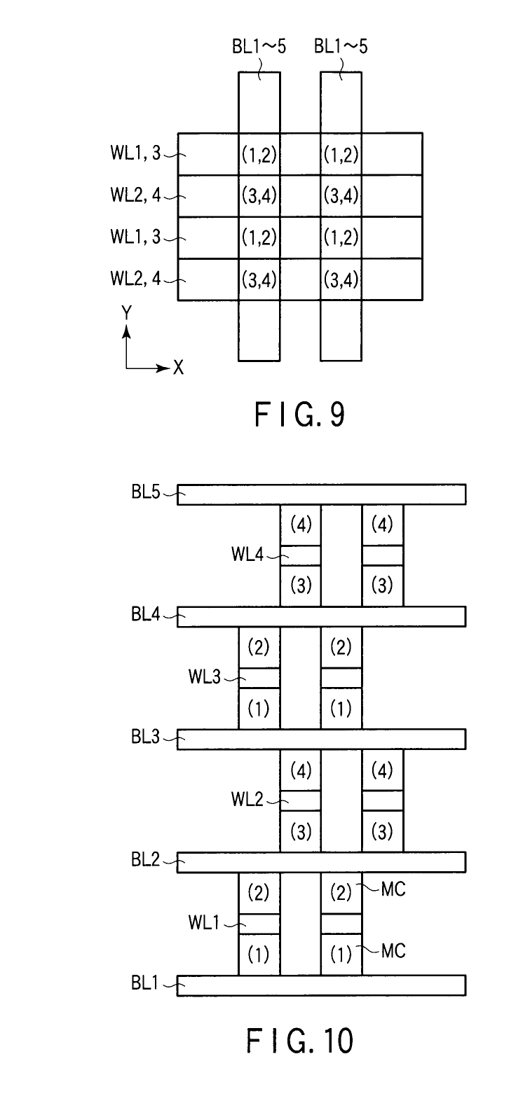

FIG. 9 is a bird's-eye view of the memory cell array 20. FIG. 10 is a side view of the memory cell array 20 as viewed in the X-direction. In FIG. 10, numbers are attached to the memory cells MC. The same number is attached to the memory cells MC that are arranged on the same level, that is, that are connected to the same bit line group and word line group, and the same number is also attached to the memory cells MC that are arranged in the same position in the bird's eye view. The numbers in FIGS. 9 and 10 represent the common memory cells MC.

It can be understood from FIGS. 9 and 10 that word line groups WL1, WL3 of the odd-numbered layers and word line groups WL2, WL4 of the even-numbered layers are shifted by half the pitch in the Y-direction. Specifically, word line groups WL1, WL3 of the odd-numbered layers are arranged in the same positions in the bird's eye view of FIG. 9. Further, word line groups WL2, WL4 of the even-numbered layers are arranged in the same positions in the bird's eye view of FIG. 9. In addition, bit line groups BL1 to BL5 are arranged in the same positions in the vertical direction and, specifically, they are arranged in the same positions in the bird's eye view of FIG. 9.

The memory cells MC are uniformly arranged in the Y-direction of the memory cell array 20 by thus changing the arrangement of word line groups WL. As a result, since the flatness of each layer can be maintained even if the memory cells MC of plural layers are laminated, the memory cell array 20 in which variation in the shape is suppressed and distortion is reduced can be configured.

Further, only the arrangement of word line groups WL is changed and the arrangement of bit line groups BL is not changed. As a result, the manufacturing cost can be reduced in comparison with that in the first embodiment. The other effects are the same as those of the first embodiment.

### Third Embodiment

In a third embodiment, odd- and even-numbered layers of only bit line groups are arranged to shift from one another. That is, the laminated word line groups are arranged in the same positions in the vertical direction, and the bit line groups of the odd-numbered layers and the bit line groups of the even-numbered layers among the laminated bit line groups are arranged to shift from one another by half the pitch, for example.

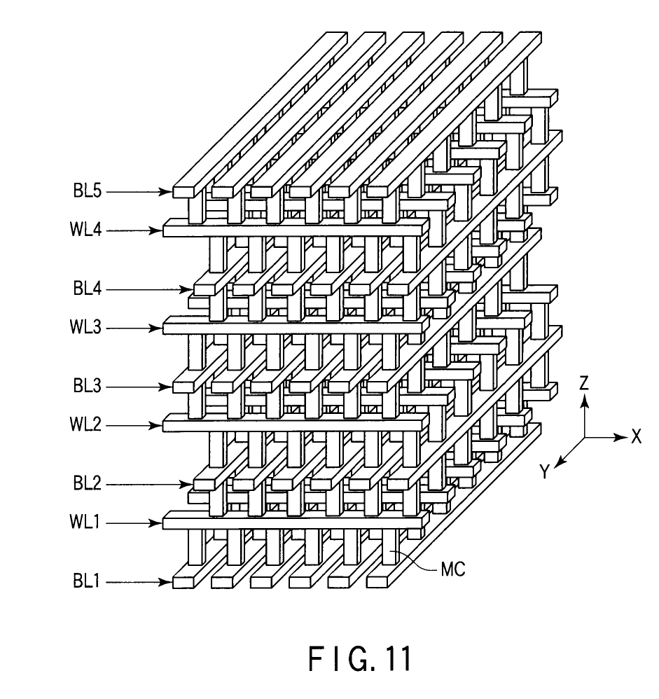

FIG. 11 is a perspective view showing the structure of a memory cell array 20 according to the third embodiment. In the memory cell array 20, bit line groups BL and word line groups WL are alternately laminated in a Z-direction. In FIG. 11, a case wherein memory cells MC of eight layers are laminated is shown as one example, but the number of laminated layers is not limited to this case and can be determined according to the restriction of the peripheral circuit and the manufacturing method. Each memory cell MC is arranged in an intersection area between a bit line BL extending in a Y-direction and a word line WL extending in an X-direction and is electrically connected thereto.

As shown in FIG. 11, a bit line group BL2 is shifted in the X-direction with respect to a bit line group BL1 that is adjacent thereto with a word line group WL1 disposed therebetween. Bit line groups BL of plural layers are laminated with the above relationship maintained. That is, the bit line groups of the odd-numbered layers and the bit line groups of the even-numbered layers are arranged to shift from one another in the X-direction. For example, the shifting distance is set to half the pitch of the bit lines in the interconnection layer of the same level. Further, the width of bit line BL and the distance between bit lines BL are set to half the pitch.

Word line groups WL are arranged in the same positions in the vertical direction. That is, unlike the bit line groups, word line groups WL of the odd-numbered layers and word line groups WL of the even-numbered layers are arranged without being shifted.

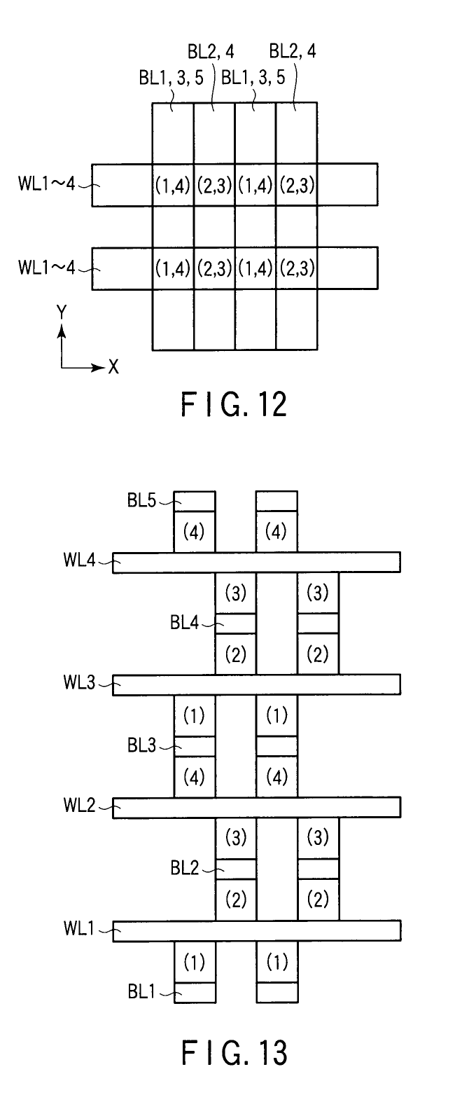

FIG. 12 is a bird's-eye view of the memory cell array 20. FIG. 13 is a side view of the memory cell array 20 as viewed in the Y-direction. In FIG. 13, numbers are attached to the memory cells MC. The same number is attached to the memory cells MC that are arranged on the same level, that is, that are connected to the same bit line group and word line group and the same number is attached to the memory cells MC that are arranged in the same position in the bird's eye view. The numbers in FIGS. 12 and 13 represent the common memory cells MC.

It can be understood from FIGS. 12 and 13 that bit line groups BL1, BL3, BL5 of the odd-numbered layers and bit line groups BL2, BL4 of the even-numbered layers are shifted by half the pitch in the Y-direction. Specifically, bit line groups BL1, BL3, BL5 of the odd-numbered layers are arranged in the same positions in the bird's eye view of FIG. 12. Further, bit line groups BL2, BL4 of the even-numbered layers are arranged in the same positions in the bird's eye view of FIG. 12. In addition, word line groups WL1 to WL4 are arranged in the same positions in the vertical direction and, specifically, they are arranged in the same positions in the bird's eye view of FIG. 12.

The memory cells MC are uniformly arranged in the X-direction of the memory cell array 20 by thus changing the arrangement of bit line groups BL. As a result, since the flatness of each layer can be maintained even if the memory cells MC of plural layers are laminated, the memory cell array 20 in which variation in the shape is suppressed and distortion is reduced can be configured.

Further, only the arrangement of bit line groups BL is changed and the arrangement of word line groups WL is not changed. As a result, the manufacturing cost can be reduced in comparison with that in the first embodiment. The other effects are the same as those of the first embodiment.

In each of the above embodiments, a PCRAM, MRAM or the like can be used other than the ReRAM as the resistance-change memory. Further, each of the above embodiments can be generally applied to cross-point memories and the application range thereof is not limited to the resistance-change memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
first select line groups laminated in a vertical direction, and each including first select lines extending in a first direction;
second select line groups alternately laminated with the first select line groups, and each including second select lines extending in a second direction that intersects with the first direction; and
memory cells arranged between the first select lines and the second select lines,
wherein even-numbered layers and odd-numbered layers of the first select line groups are arranged to be shifted in the second direction.

2. The device of claim 1, wherein the even-numbered layers and odd-numbered layers are shifted by half a pitch of the select lines.

3. The device of claim 2, wherein width of the select line and a distance between the select lines are set to half the pitch.

4. The device of claim 1, wherein width of the select line is set equal to a distance between the select lines.

5. The device of claim 1, wherein the second select line groups are arranged in same positions in the vertical direction.

6. The device of claim 1, wherein each of the memory cells includes a variable resistance element that has two resistance states and a select element serially connected to the variable resistance element.

7. The device of claim 6, wherein the select element is a diode.

8. A semiconductor memory device comprising:
first select line groups laminated in a vertical direction, and each including first select lines extending in a first direction;
second select line groups alternately laminated with the first select line groups, and each including second select lines extending in a second direction that intersects with the first direction; and
memory cells arranged between the first select lines and the second select lines,
wherein even-numbered layers and odd-numbered layers of the first select line groups are arranged to be shifted in the second direction, and
even-numbered layers and odd-numbered layers of the second select line groups are arranged to be shifted in the first direction.

9. The device of claim 8, wherein
the even-numbered layers and the odd-numbered layers of the first select line groups are shifted by half a pitch of the select lines, and
the even-numbered layers and the odd-numbered layers of the second select line groups are shifted by half the pitch.

10. The device of claim 9, wherein width of the select line and a distance between the select lines are set to half the pitch.

11. The device of claim 8, wherein width of the select line is set equal to a distance between the select lines.

12. The device of claim 8, wherein each of the memory cells includes a variable resistance element that has two resistance states and a select element serially connected to the variable resistance element.

13. The device of claim 12, wherein the select element is a diode.
